(19) United States
(12) Patent Application Publication
(10) Pub. No.: US 2025/0221069 A1
(43) Pub. Date: Jul. 3, 2025

(54) CMOS IMAGE SENSING DEVICE

(71) Applicant: Samsung Electronics Co., Ltd., Suwon-si (KR)

(72) Inventors: Hwanwoong KIM, Suwon-si (KR); Hyuncheol KIM, Suwon-si (KR)

(73) Assignee: Samsung Electronics Co., Ltd., Suwon-si (KR)

(21) Appl. No.: 18/931,829

(22) Filed: Oct. 30, 2024

(30) Foreign Application Priority Data
Dec. 29, 2023 (KR) 10-2023-196988

(51) Int. Cl. H01L 27/146; H04N 25/51; H04N 25/57; H04N 25/77

(52) U.S. Cl. CPC H10F 39/80373; H04N 25/51; H04N 25/57; H04N 25/77; H10F 39/014; H10F 39/802; H10F 39/80377

(57) ABSTRACT

An image sensing device includes: a substrate; and a plurality of pixels isolated by an insulating film disposed within the semiconductor substrate. The plurality of pixels share a first active region, wherein at least one of the plurality of pixels comprises a photoelectronic conversion element and a transfer transistor. The photoelectronic conversion element is connected to the first active region by the transfer transistor. The first active region and a first floating diffusion region are connected by the transfer transistor. The first floating diffusion region is connected to a gate of a source follower transistor, and the first floating diffusion region is connected to a second floating diffusion region through a first transistor. The first transistor is turned off when an operating mode is a first mode. The first transistor is turned on when the operating mode is a second mode different from the first mode.

### CROSS-REFERENCE TO RELATED APPLICATION

This application is based on claims benefit under 35 U.S.C. § 119 to Korean Patent Application No. 10-2023-0196988, filed on Dec. 29, 2023, in the Korean Intellectual Property Office, the disclosure of which is incorporated herein by reference in its entirety.

### BACKGROUND

### 1. Field

The disclosure relates to a complementary metal-oxide-semiconductor (CMOS) image sensing device, and more specifically, to an image sensing device in which a plurality of pixels share a pixel image signal processing circuit. The disclosure also relates to manufacturing and operating methods of the CMOS image sensing device, and to an electronic device including the CMOS image sensing device.

### 2. Description of Related Art

An image sensing device converts an optical signal into an electrical signal, and basically plays a role in electronic devices corresponding to that of the eyes providing vision among human sense organs. An image sensing device is used in consumer electronics such as a digital camera, a digital camcorder and a camera for a cell phone. In addition, an image sensing device is being applied to an autonomous vehicle, a security device, a drone, a robot and the like.

An image sensing device becomes more integrated and miniaturized to increase resolution. In addition, to provide a clear image even when shooting at night or in a dark place, a wide dynamic range of an image sensing device is required.

### SUMMARY

Provided is an image sensing device having high conversion gain. Provided is an image sensing device having high conversion gain with low noise.

Provided is an image sensing device having a high dynamic range. Provided is an image sensing device having an architecture in which a plurality of pixels share a pixel processing circuit and having high conversion gain and/or low noise.

According to an aspect of the disclosure, a complementary metal-oxide-semiconductor (CMOS) image sensing device includes: a semiconductor substrate including a plurality of pixel regions; an insulating film disposed within the semiconductor substrate and disposed between the plurality of pixel regions; and a first active region disposed between the plurality of pixel regions, wherein a photoelectronic conversion element and a transfer transistor are disposed in at least one of the plurality of pixel regions, wherein the photoelectronic conversion element is connected to the first active region by the transfer transistor, wherein the first active region and a first floating diffusion region are connected by at least one of the transfer transistors, wherein the first floating diffusion region is connected to a gate of a source follower transistor, and the first floating diffusion region is connected to a second floating diffusion region through a first transistor, and wherein the first transistor is turned off when an operating mode is a first mode, and the first transistor is turned on when the operating mode is a second mode different from the first mode.

According to an aspect of the disclosure, an image sensor includes: a reset transistor connected to a pixel bias voltage node configured to supply a pixel bias voltage; first to fourth transfer transistors connected between first to fourth photodiodes and a floating diffusion region, respectively; a first transistor connected between the floating diffusion region and the reset transistor; a source follower transistor connected to the floating diffusion region; and a selection transistor connected between the source follower transistor and a column line, wherein the reset transistor is turned on and the first transistor is turned off during a turn-on time of the selection transistor in a first mode, and the reset transistor is turned off and the first transistor is turned on during a turn-on time of the selection transistor in a second mode, and wherein a conversion gain in the second mode is less than a conversion gain in the first mode.

### BRIEF DESCRIPTION OF THE DRAWINGS

The above and other aspects, features, and advantages of the disclosure will be more clearly understood from the following detailed description, taken in conjunction with the accompanying drawings, in which:

FIG. 1 is a pixel layout according to an example embodiment of the disclosure;

FIG. 2 is a circuit diagram including a pixel and a pixel processing circuit according to an example embodiment of the disclosure;

FIG. 3A is a pixel arrangement diagram according to an example embodiment of the disclosure, and FIG. 3B is a partial cross-sectional view taken along line A-A′;

FIG. 4A is a pixel arrangement diagram according to an example embodiment of the disclosure, and FIGS. 4B and 4C are partial cross-sectional views taken along line B-B′;

FIG. 5A is a pixel arrangement diagram according to a third embodiment of the disclosure, and FIG. 5B is a partial cross-sectional view taken along line A-A′;

FIG. 6A is a pixel arrangement diagram according to a variation of the third embodiment of the disclosure, and FIG. 6B is a partial cross-sectional view taken along line A-A′;

FIG. 7A is a pixel arrangement diagram according to a fourth embodiment of the disclosure, and FIG. 7B is a partial cross-sectional view taken along line A-A′;

FIG. 8 is a schematic diagram showing elements and connecting transistors passing from a photodiode to a pixel bias voltage node;

FIG. 9 is an operation timing diagram of a pixel processing circuit in a high conversion gain mode;

FIG. 10 is a potential diagram according to the operation timing steps of FIG. 9;

FIG. 11 is an operation timing diagram of a pixel processing circuit in a low conversion gain mode;

FIG. 12 is a potential diagram according to the operation timing steps of FIG. 11;

FIG. 13 is an operation timing diagram in a four-sum operating mode according to an example embodiment of the disclosure;

FIG. 14 is an operation timing diagram in an individual pixel operating mode according to an example embodiment of the disclosure;

FIGS. 15A to 15G are manufacturing process diagrams of the source follower transistor and the first floating diffusion region according to an example embodiment of the disclosure;

FIGS. 16A to 16H are manufacturing process diagrams of the source follower transistor with the Fin Field-Effect Transistor (FinFET) structure according to an example embodiment of the disclosure.

FIG. 17 is a diagram simply showing a pixel array in which four pixels are combined to form one color of a Bayer pattern according to an example embodiment of the disclosure;

FIG. 18 a diagram simply showing a pixel array in which sixteen pixels are combined to form one color of a Bayer pattern according to another embodiment of the disclosure; and

FIG. 19 is a block diagram of a CMOS image sensing device including a pixel and a pixel processing circuit according to an example embodiment of the disclosure.

### DETAILED DESCRIPTION

Hereinafter, example embodiments of the disclosure will be described with reference to the accompanying drawings.

The terms as used in the disclosure are provided to merely describe specific embodiments, not intended to limit the scope of other embodiments. Singular forms include plural referents unless the context clearly dictates otherwise. The terms and words as used herein, including technical or scientific terms, may have the same meanings as generally understood by those skilled in the art. The terms as generally defined in dictionaries may be interpreted as having the same or similar meanings as or to contextual meanings of the relevant art. Unless otherwise defined, the terms should not be interpreted as ideally or excessively formal meanings. Even though a term is defined in the disclosure, the term should not be interpreted as excluding embodiments of the disclosure under circumstances.

Before undertaking the detailed description below, it may be advantageous to set forth definitions of certain words and phrases used throughout the disclosure. The term “couple” and the derivatives thereof refer to any direct or indirect communication between two or more elements, whether or not those elements are in physical contact with each other. The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

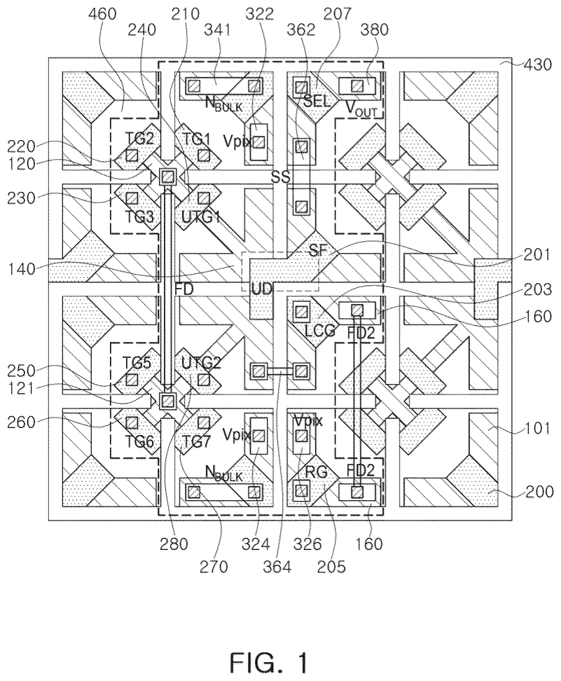

FIG. 1 is a pixel layout according to an example embodiment of the disclosure. The layout diagram of FIG. 1 shows four (4) pixel regions in an upper right portion (first quadrant), four (4) pixel regions in an upper left portion (second quadrant), four (4) pixel regions in a lower left portion (third quadrant), and four (4) pixel regions in a lower right portion (fourth quadrant). That is, a total of 16 pixel regions are shown.

Further referring to FIG. 1, a trench may be formed in a substrate to define an active region 101 on an upper surface of the substrate. By filling the trench with an insulating film, elements to be formed in the active region may be electrically isolated. Depending on a depth of the trench, the trench may include a shallow trench isolation (STI) 460 extending from the upper surface of the substrate to a certain depth and a deep trench isolation (DTI) 430 extending from the upper surface of the substrate to a greater depth.

The DTI 430 may define the active region and partition the pixel regions. The DTI 430 may penetrate the substrate and extend from the upper surface of the substrate to the opposite surface. A photoelectronic conversion element may be formed in the pixel region of the substrate partitioned by the DTI 430. For example, a photodiode may be formed by implanting impurities into the substrate. The photodiode may include a PN or PNP junction photodiode, and with the integration and miniaturization of elements, may include a deep photodiode in which a diode capacity is expanded by utilizing a portion of the photodiode near to a lower surface of the substrate as a N-type portion.

The photodiode of the pixel region may be connected to a transfer transistor. Referring to FIG. 1, the photodiodes in the pixel regions of the first to fourth quadrants may be connected to four transfer transistors, respectively.

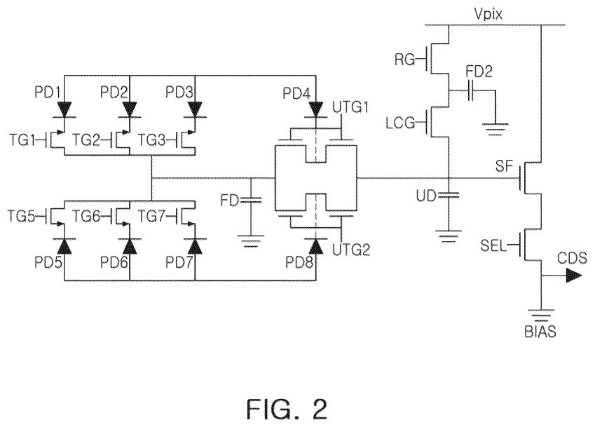

Each transfer transistor may include a gate comprising doped polysilicon. For example, the photodiodes PD1, PD2, PD3 and PD4 of the four pixel regions disposed in the second quadrant may be connected to four transfer transistors TG1 210, TG2 220, TG3 230 and UTG1 240, respectively. In the meantime, referring to FIG. 1 and FIG. 2, the photodiodes PD5, PD6, PD7 and PD8 of the four pixel regions disposed in the third quadrant may be connected to four transfer transistors TG5 250, TG6 260, TG7 270 and UTG2 280, respectively.

The depth of the DTI 430 in one device may not necessarily be uniform. In an example embodiment, four shared pixel regions may be used by pairing them in pairs. For example, when pairing upper and lower photodiodes, the DTI surrounding the four pixel regions may extend to a lower surface of the substrate, while the DTI between the four pixels may not extend to the lower surface of the substrate but only extends to a certain depth.

In an example embodiment of the disclosure, four pixel regions located in each quadrant may share one active region. Referring to FIG. 1, the four pixel regions located in the second quadrant may share a first active region 120. The four pixel regions located in the third quadrant may share a second active region 121. In the disclosure, one active region shared by the four pixel regions located in each quadrant may be formed in one corner of the DTI 430, for example, in a corner area shared by the four pixel regions. The DTI 430 may not extend to the corner region shared by the four pixel regions, so that the four pixels located in each quadrant share one active region.

Negative charges generated in the photodiode due to an opening (turn-on) operation of the transfer transistor in each pixel may move to the active region (e.g., the first active region 120 or the second active region 121) opposite the gate of the transfer transistor.

A portion of the active region shared by each pixel region may include a floating diffusion region. The negative charges moved to the floating diffusion region by the opening operation of the transfer transistor may be stored in the floating diffusion region based on a capacitance value of the floating diffusion region. The first active region 120 may have a floating diffusion region, and the second active region 121 may have a floating diffusion region. When formed with the same layout and process recipe, the first active region 120 and the second active region 121 may have the same capacitance.

The disclosure is directed to a pixel processing circuit. In FIG. 1, blocks demarcated by grid lines represent the pixel processing circuit. The pixel processing circuit may include a photodiode PD located in the pixel region, a transfer transistor TG located in the pixel region, a source follower transistor SF 201 that amplifies the negative charges generated in the photodiode into an electrical signal, a selection transistor SEL 207, a pixel bias voltage node 322, 324 and 326, and a node 341 that applies a ground voltage or a negative voltage to the substrate or the pixel processing circuit. Referring to the FIG. 1, the node 341 for applying a bias voltage to the substrate may be connected to a gate adjacent to the node 341, thereby preventing the adjacent gate from floating.

The active region that provides a source of the selection transistor SEL 207 may be connected to an output node 380, select a pixel to transmit the electrical signal amplified by the source follower transistor SF 201 and transmit the same to an output line.

In order to provide an image sensing device with small noise, a high amplification factor and a high signal-to-noise ratio (SNR), it may be advantageous to use a pixel processing circuit with excellent analog characteristics. For example, a planar gate may be used as the gate of the source follower transistor SF 201. In this case, a width and/or size of the planar gate may be made wider or larger. In an example embodiment, a FinFET-type gate may be used as the gate of the source follower transistor SF 201 instead of a planar gate so as to provide the source follower transistor SF 201 that may prevent leakage current, reduce a short channel effect, and have a better amplification ratio.

Furthermore, when a deep photodiode is employed, a vertical transfer gate with a gate pole extending to an N region of the deep photodiode may be used to increase electron mobility, and preferably a dual vertical transfer gate with two poles may be used.

In an example embodiment of the disclosure, a plurality of pixels provided by the pixel regions may share a pixel processing circuit. When a plurality of pixels share a pixel processing circuit, integration of pixels may be realized and at the same time, the problem of deteriorating signal characteristics may be prevented by miniaturizing a size of an analog circuit, that is, the pixel processing circuit.

As previously mentioned, four pixels provided four pixel regions arranged in each quadrant may be grouped and connected to one pixel processing circuit. Alternatively, eight pixels provided by eight pixel regions may be connected to one pixel processing circuit as shown in FIG. 1. When eight pixels are connected to one pixel processing circuit as shown in FIG. 1, the first active region 120 and the second active region 121 may be connected to each other by wirings and share a floating diffusion region. In the disclosure, the number of shared pixels is not limited to 4 or 8, and may be further expanded depending on an architecture and a circuit design.

However, as the number of pixels sharing the pixel processing circuit increases, a capacitance of the floating diffusion region may increase. When the capacitance value of the floating diffusion region is great, the source follower transistor SF 201 may operate well in response to a large amount of charges, but may not operate well in response to an amount of charges.

As such, in order to realize a mode that operates well with a small amount of charges, that is, a high conversion gain mode, the disclosure is directed to a first floating diffusion region UD 140 with a low capacitance. And, the active regions 120 and 121 may be separated from the first floating diffusion region UD 140 by transfer gates 240 and 280. Referring to FIG. 1, the transfer gates 240 and 280 may be respectively connected to the first active region 120 and the second active region 121, and may be connected to the first floating diffusion region UD 140.

In an example embodiment of the disclosure, an area of the floating diffusion region UD 140 of the first active region 120 may be greater than an area of the first floating diffusion region UD 140. For example, the area of the first floating diffusion region UD 140 may be ¼ to ½ times the area of the floating diffusion region of the first active region 120. The transfer gates UTG1 240 and UTG2 280 may be the same as other transfer gates or may be gates of different shapes.

In an example embodiment of the disclosure, a doping concentration of N-type impurities in the first floating diffusion region UD 140 may be higher than a doping concentration of N-type impurities in the floating diffusion region of the first active region 120.

The transfer gates UTG1 240 and UTG2 280 may serve to move negative charges stored in the photodiode of the pixel region connected to a drain of the respective transfer gate to the first floating diffusion region UD 140. In addition, the transfer gates UTG1 240 and UTG2 280 may also serve to separate the first active region 120 or the second active region 121 from the first floating diffusion region UD 140, and moving negative charge stored in the photodiode of the other shared pixel region to the first floating diffusion region UD 140.

As such, pixels sharing a pixel processing circuit may physically divide the active regions 120 and 121 and the first floating diffusion region UD 140 that are shared by the plurality of pixels, by connecting the first active region 120 or the second active region 121 to the first floating diffusion region UD 140 via one transfer gate UTG1 240 or UTG2 280. Accordingly, embodiments of the disclosure may realize the first floating diffusion region UD 140 with low capacitance, and thus, may be directed to a pixel processing circuit having high conversion gain.

In addition, in an example embodiment of the disclosure, noise may be reduced by disposing the source follower transistor SF 201 and the first floating diffusion region UD 140 adjacent to each other.

Continuing to refer to FIG. 1, a gate extension of the gate of the source follower transistor SF 201 may be disposed to contact the first floating diffusion region UD 140 across the DTI 430. The gate of the source follower transistor SF 201 may be formed on the substrate via a gate oxide film, and a portion where the gate extension extends and contacts the first floating diffusion region UD 140 may substantially contact the substrate without a gate oxide film.

The gate of the source follower transistor SF 201 and the gate extension thereof may include a semiconductor material, and specifically silicon. More specifically, it may include crystalline silicon and amorphous silicon, and further more specifically, it may include polysilicon. The silicon includes intrinsic and doped silicon, and the doped impurities may be N-type impurities or a P-type impurities.

As used herein, the expression ‘substantially’ contacting may include a structure that is directly connected without an insulating film in the middle, and may also include a feature of further applying a conductive liner material or a conductive barrier layer to a contact surface in order to lower a contact resistance or to increase adhesion to an interface with an insulating film so as to prevent peeling. Alternatively, although the above connection is intended, the case in which a natural film is formed through a process will also be interpreted as an included feature.

In some embodiments, the first floating diffusion region UD 140 and the gate extension of the gate of the source follower transistor SF 201 are made of polysilicon, since a polysilicon-polysilicon connection has a lower junction capacitance than a metal-metal or metal-polysilicon connection so embodiments of the disclosure are directed to the first floating diffusion region UD 140 having high conversion gain.

In some embodiments, a plurality of the floating diffusion regions 140 are connected to the source follower transistor SF 201. Referring to FIG. 1, a second floating diffusion region FD2 160 may be disposed along with the first floating diffusion region UD 140. The second floating diffusion region FD2 160 may be connected to the first floating diffusion region UD 140 via a first transistor LCG 203, and may be connected to a pixel bias voltage node 326 via a reset transistor RG 205 at the opposite side. In the disclosure, an operation may be possible in various modes by providing a plurality of floating diffusion regions. As an example embodiment of the disclosure, the first floating diffusion region UD 140 may have a relatively great capacitance value, and the second floating diffusion region

FD2 160 may have a relatively less capacitance value. Specifically, in order to realize a high conversion gain mode, the first transistor LCG 203 may be turned off, and only the first floating diffusion region UD 140 may be used. In a low conversion gain mode, the first transistor LCG 203 may be turned on, and the first floating diffusion region UD 140 and the second floating diffusion region FD2 160 may be used together. In the disclosure, a capacitance of the second floating diffusion region FD2 160 may be greater than a capacitance of the first floating diffusion region UD 140. As a specific example, the second floating diffusion region FD2 160 may use a capacitance by means of a junction capacitance with the substrate. Alternatively, a capacitance that is the sum of the junction capacitance and a line capacitance by wirings may be used. In this case, the second floating diffusion region FD2 160 with a great capacitance value may be realized despite its narrow cross-sectional area.

In the disclosure, the wirings may include vertical wirings and horizontal wirings. The vertical wirings may include vias and contacts, and the horizontal wirings may include M1 to Mn multilayer wirings. In addition, in the arrangement of pixels of the disclosure, adjacent active regions may be connected in various routing methods using wirings. Referring to FIG. 1, a source of the source follower transistor SF 201 and a drain of the select transistor SEL 207 may be connected using a wire SS 362.

In an example embodiment of the disclosure, the first floating diffusion region UD 140 and the first transistor LCG 160 may be connected by a wire 364. In addition, in FIG. 1, the first transistor LCG 160 and the reset transistor RG 205, which are spaced apart from each other, may be connected by wirings, and the connection wirings thereof may act as a line capacitance of the second floating diffusion region FD2 160 so as to contribute a portion of a capacitance of the second floating diffusion region FD2 160.

FIG. 2 is a circuit diagram including a pixel and a pixel processing circuit according to an example embodiment of the disclosure. That is, FIG. 2 is a circuit diagram of the layout of FIG. 1.

FIG. 2 illustrates four photodiodes PD1 to PD4. Each of the photodiodes may have a P-type node and an N-type node. The N-type node may be connected to transfer transistors TG1 to TG3 and UTG1, and the P-type node may be connected to a ground bias. The transfer transistors TG1 to TG3 and UTG1 may share their drains, and the shared drain may correspond to the first active region 120 of FIG. 1. Among the transfer transistors TG1 to TG3 and UTG1, the transfer transistor UTG1 connected to the fourth photodiode PD4 may also be connected to the first active region 120, and may also be connected to the first floating transistor diffusion region UD at the opposite node of the first active region 120.

In some embodiments, four photodiodes PD5 to PD8 may be below the four photodiodes PD1 to PD4, and each of the photodiodes may have a P-type node and an N-type node. The N-type node may be connected to transfer transistors TG5 to TG7 and UTG2, and the P-type node may be connected to a ground bias. The transfer transistors TG5 to TG7 and UTG2 may share their drains, and the shared drain may correspond to the second active region 121 of FIG. 1. Among the transfer transistors, the transfer transistor UTG2 connected to the eighth photodiode PD8 may also be connected to the second active region 121, and may also be connected to the first floating diffusion region UD at the opposite node of the second active region 121. The first active region 120 and the second active region 121 may be connected to each other, and the first active region 120 and the second active region 121 may include a floating diffusion region FD.

The first floating diffusion region UD may be connected to the transfer transistors UTG1 240 and UTG2 280 and to the gate of the source follower transistor SF. The first floating diffusion region UD may have a capacitance value including a junction capacitance. The capacitance value of the first floating diffusion region UD may be less than a capacitance value(s) of the first active region 120 and/or the second active region 121, thereby making it suitable for a high conversion gain mode. In the disclosure, a high conversion gain mode may operate in low illumination. In an example embodiment, in low illumination, a plurality of pixels may be used as one pixel (herein, referred to as a ‘cluster pixel’), and the negative charges collected from the plurality of pixels may be combined and used. In the disclosure, four pixels may be used as one cluster pixel, and as a variation, eight or sixteen pixels may be used as one cluster pixel.

In addition, an image sensing device in an example embodiment of the disclosure, and pixels and a pixel processing circuit included therein, may have a floating diffusion region with a small capacitance and a floating diffusion region with a large capacitance, and may use the floating diffusion region with a small capacitance, or use the floating diffusion region with a small capacitance and the floating diffusion region with a large capacitance together, depending on an operating mode.

In an implementation as described above, the first floating diffusion region UD may be connected to the first transistor LCG. The first transistor LCG may be connected to the second floating diffusion region FD2. When the first transistor LCG is turned on, it may be possible to operate with a large capacitance by using both of the first floating diffusion region UD and the second floating diffusion region FD2. The mode using such a large capacitance may be a low conversion gain mode, and may be used in high illuminance, for example.

The source follower transistor SF may be connected to a pixel bias voltage Vpix node at a drain node thereof, and a source node thereof may be connected to a select transistor SEL. As previously mentioned, the gate of the source follower transistor SF may be connected only to the first floating diffusion region UD, or may be connected to the first floating diffusion region UD and the second floating diffusion region FD2, so as to amplify an electrical signal depending on the amount of negative charges transferred from the photodiodes PD1 to PD8 (Q-CV).

The select transistor SEL may serve to transfer the electrical signal amplified by the source follower transistor SF to an output node. An output line may be connected to a peripheral circuit, for example, a CDS (correlated double sampling), so that an analog signal may be converted into a digital signal according to a clock signal.

As previously described in FIG. 1, the first floating diffusion region UD 140 and the source follower transistor SF 201 may be disposed close to each other in order to reduce noise and lower the capacitance value. In an example embodiment of the disclosure, the first floating diffusion region UD 140 and the source follower transistor SF 201 may be disposed adjacent to each other. Specifically, the gate of the source follower transistor SF 201 may be disposed adjacent to the first floating diffusion region UD 140 with the DTI 430 interposed therebetween.

The disclosure may be implemented in various embodiments and variations.

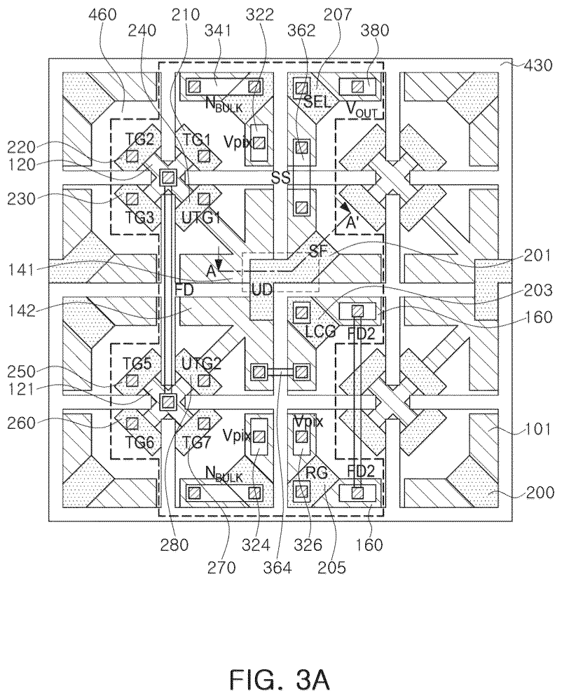

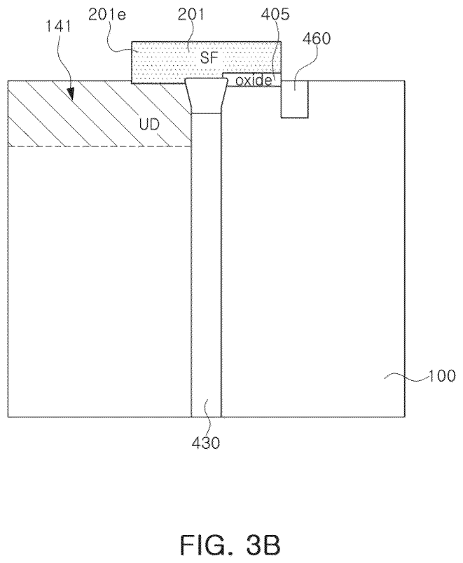

FIG. 3A is a pixel arrangement diagram according to an example embodiment of the disclosure, and FIG. 3B is a partial cross-sectional view taken along line A-A′. FIG. 3A is the same embodiment as FIG. 1. A gate extension 201e of the gate of the source follower transistor SF 201 may be disposed to contact the first floating diffusion region UD 141, 142 across the DTI 430. Referring to FIG. 3B, a gate of a source follower transistor SF 201 may be formed on the substrate 100 via the gate oxide film 405, and the portion where the gate extension 201e may extend across the DTI 430 and contact the first floating diffusion region UD 141, 142 may substantially contact the substrate 100 without a gate oxide film.

In addition, the gate extension 201e may extend to the adjacent first floating diffusion region UD (active region) 141, while extending to another active region 142 adjacent to the first floating diffusion region UD (active region) 141 across the DTI 430, and substantially contact the substrate 100 without the gate oxide film 405.

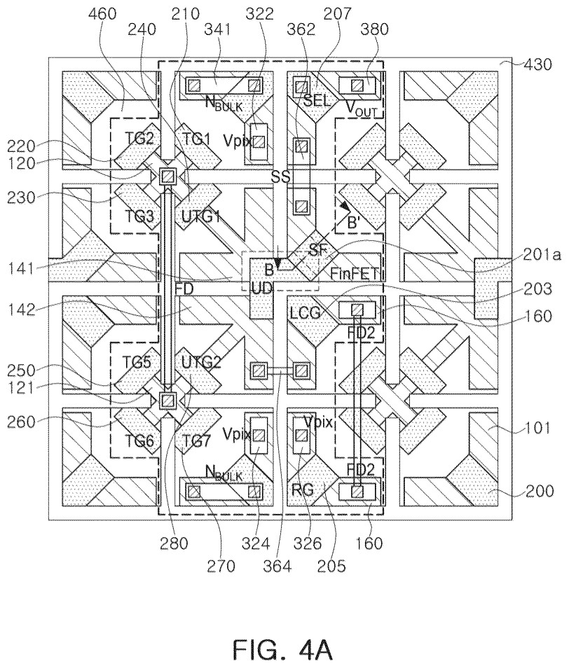

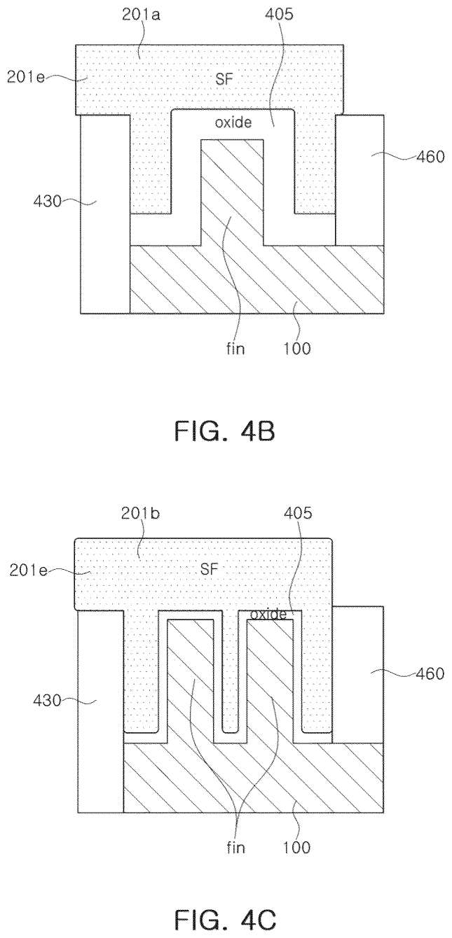

FIG. 4A is a pixel arrangement diagram according to an example embodiment of the disclosure, and FIGS. 4B and 4C are partial cross-sectional views taken along line B-B′. Referring to FIG. 4A, it is the same as FIG. 3A, but differs from FIG. 3A in that a transistor having a FinFET type gate is used as a source follower transistor SF (201a). As shown in FIG. 4B, in this embodiment, the STI 460 and the DTI 430 may be formed on a substrate 100 to partition an active region, and one fin is formed in the active region. A gate oxide film 405 may be formed on a surface of the fin, and the gate of the source follower transistor SF (201a) may be formed on the gate oxide film 405. In some embodiments, the gate of the source follower transistor SF (201a) may extend across the DTI 430, and a gate extension 201e may substantially contact the first floating diffusion region UD 141, 142 as shown in FIG. 3B. In addition, the gate extension 201e may extend to the adjacent active region 141 while extending another active region 142 adjacent to the active region 141 across the DTI 430, and may substantially contact the substrate 100 without the gate oxide layer 405.

In the embodiment shown in FIG. 4C, a shape of the FinFET-type gate may be different from a shape of the gate according to the embodiment shown in FIG. 4B. Referring to FIG. 4C, two fins may be formed in the active region of a substrate (a semiconductor substrate) 100, the gate oxide film 405 may be formed thereon, and a gate material may be applied on the gate oxide film 405 to form a source follower transistor SF 201b.

In some embodiments, a gate of the source follower transistor SF 201b may extend across the DTI 430, and a gate extension portion 201e of the gate may substantially contact the first floating diffusion region UD 141, 142 as shown in FIG. 3B. In addition, the gate extension 20le may extend to the adjacent active region 141 while extending another active region 142 adjacent to the active region 141 across the DTI 430, and may substantially contact the substrate 100 without the gate oxide layer 405.

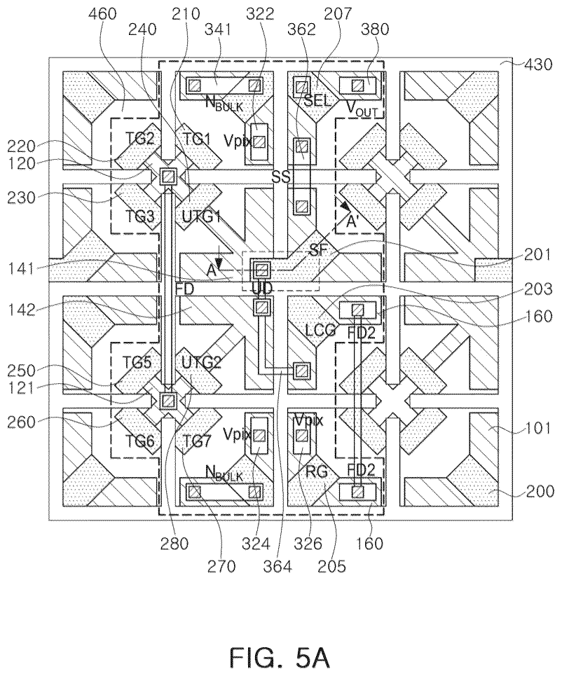

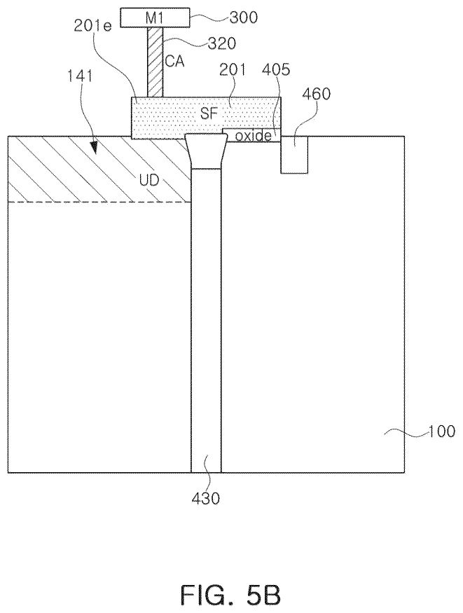

FIG. 5A is a pixel arrangement diagram according to a third embodiment of the disclosure, and FIG. 5B is a partial cross-sectional view taken along line A-A′.

FIG. 5A has basically the same structure as FIG. 3A, but differs from FIG. 3A in the connection method between the source follower transistor SF 201 and portions of the first floating diffusion region UD 141, 142. FIG. 5B is a partial cross-sectional view taken along the cutting line A-A′ in FIG. 5A. Referring to FIG. 5B, the gate of the source follower transistor SF 201 may be formed on the substrate 100 with the gate oxide film 405 interposed therebetween to form the source follower transistor SF 201, and the gate extension portion 201e may substantially contact the portion 141 of the first floating diffusion region UD 141, 142.

In some embodiments, the gate extension 201e may be connected to the other portion 142 of the first floating diffusion region UD 141, 142 in an adjacent pixel through a contact CA 320 and a wire M1 300. At this time, a contact may be formed in the other portion 142 of the first floating diffusion region UD 141, 142.

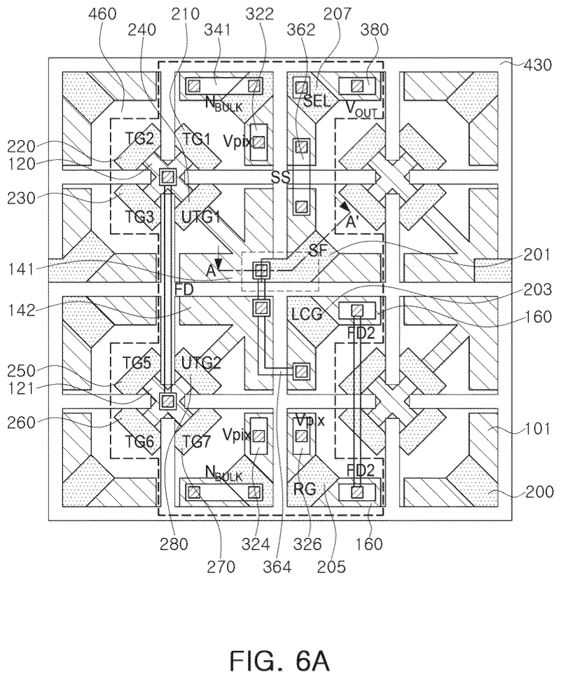

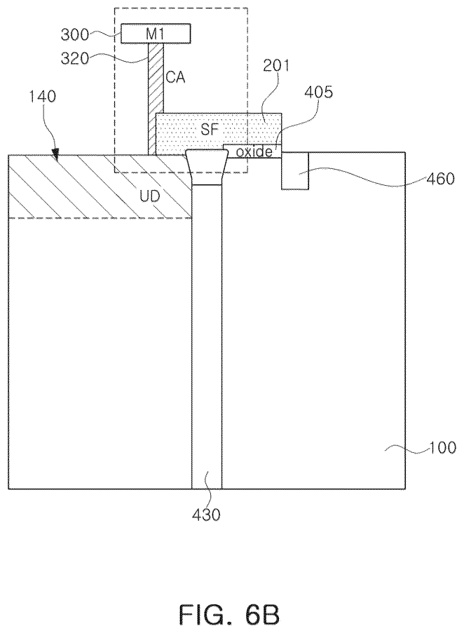

FIG. 6A is a pixel arrangement diagram according to a variation of the third embodiment of the disclosure, and FIG. 6B is a partial cross-sectional view taken along line A-A′. FIG. 6A is substantially the same as the embodiment of FIG. 5A, but in a wiring connection for connecting two adjacent portions 141 and 142 constituting the first floating diffusion region UD 141, 142, the contact CA 320 formed in the portion 141 of the first floating diffusion region UD 141, 142 may also substantially contact at least the portion 141. In an example embodiment of the disclosure, as shown in FIG. 6B, the contact CA 320 may contact the portion 141 of the first floating diffusion region UD 141, 142, while contacting the gate extension of the source follower transistor SF 201. As a contact area of the contact CA 320 with the portion 141 of the floating diffusion region UD 141, 142 and the gate extension portion 201e increases, a resistance may decrease, thereby reducing noise caused by the resistance. The contact CA 320 disposed on the portion 141 of the first floating diffusion region UD 141, 142 may be connected to a first wire M1 300 and extend across the DTI 430 to be connected to a contact 321 disposed on the other portion 142 of the floating diffusion region UD 141, 142. Furthermore, the first wire M1 300 may be further extended and connected to the source of the first transistor LCG 203.

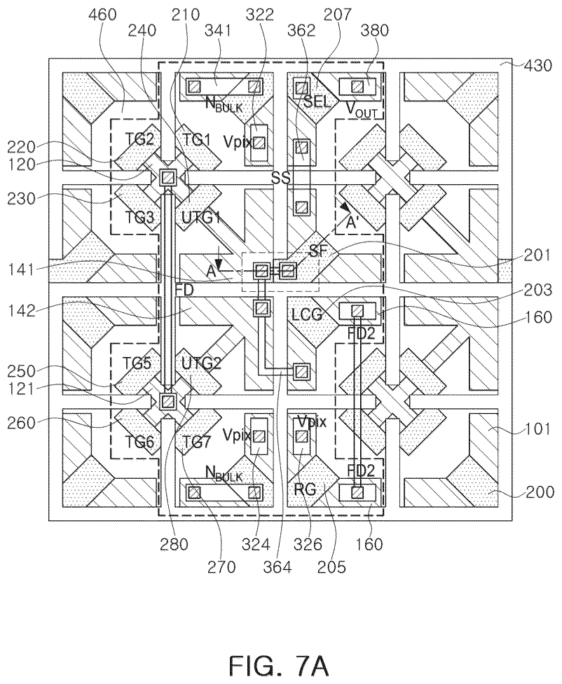

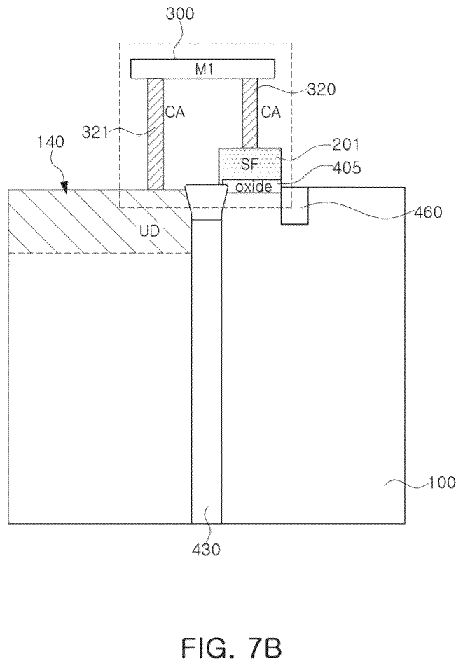

FIG. 7A is a pixel arrangement diagram according to a fourth embodiment of the disclosure. FIG. 7B is a partial cross-sectional view taken along line A-A′. The embodiment shown in FIG. 7A has a structure basically similar to that of FIG. 3A, but differ from FIG. 3A in a connection method between the source follower transistor SF 201 and the first floating diffusion region UD 141, 142 and a connection method between the portions included in the first floating diffusion region UD 141, 142. Referring to FIGS. 7A and 7B, the gate of the source follower transistor SF 201 may be formed on the substrate 100 with the gate oxide film 405 interposed therebetween. The portion 141 of the first floating diffusion region UD 141, 142 may be formed adjacent to the opposite side of the source follower transistor SF 201 with respect to the DTI 430, and the gate of the source follower transistor SF 201 and the portion 141 of the first floating diffusion region UD 141, 142 may be connected via two contacts 322 and 320 and the wire M1 301.

In addition, the pixel arrangement according to the fourth embodiment may include the wire M1 300 connecting the portion 141 and the other portion 142 constituting the first floating diffusion region UD 141, 142 across the adjacent DTI 430. Furthermore, the wire (M1, 301) may be further extended and connected to the source of the first transistor LCG 203.

According to the embodiment of the disclosure, an image sensing device may operate in a high conversion gain mode by reducing a distance between the first floating diffusion region and the source follower transistor to lower a capacitance, or by lowering a capacitance and reducing noise. In some embodiments, an image sensing device may have a wide dynamic range by varying a capacitance of the floating diffusion region depending on an operating mode.

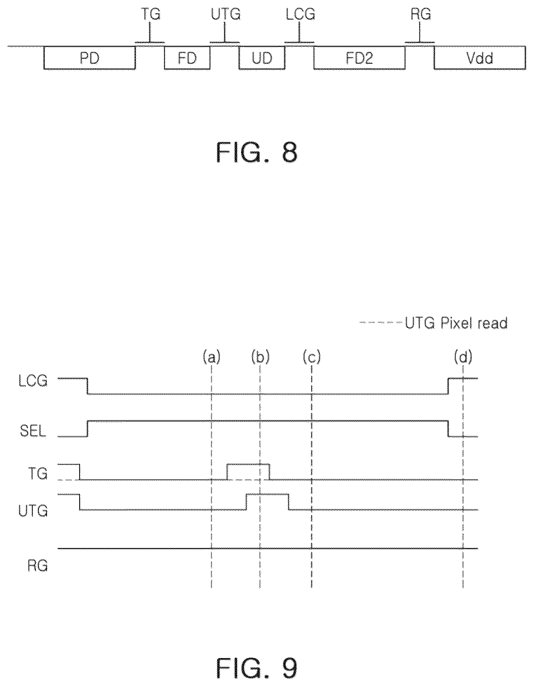

FIG. 8 is a schematic diagram showing elements and connecting transistors passing from a photodiode PD to a pixel bias voltage (Vpix) node. The pixel bias voltage Vpix may be a pixel power voltage Vdd. Referring to FIG. 8, the photodiode PD may be connected to a floating diffusion region FD having a certain capacitance value via a transfer transistor TG (FD may be in a first active region or a second active region). The floating diffusion region FD may be connected to a first floating diffusion region UD via a transfer gate UTG. The first floating diffusion region UD may be connected to a second floating diffusion region FD2 via a first transistor LCG. The second floating diffusion region FD2 may be connected to the pixel bias voltage (Vpix) node via a reset transistor RG. As used herein, “be connected via a transistor” means that an element is connected to each of both terminals of the transistor, and the two elements has a state in which they are connected or disconnected to each other according to a turn-on or turn-off operation of the transistor.

Next, the turn-on and turn-off operations of the transistor over time according to the operating mode will be explained.

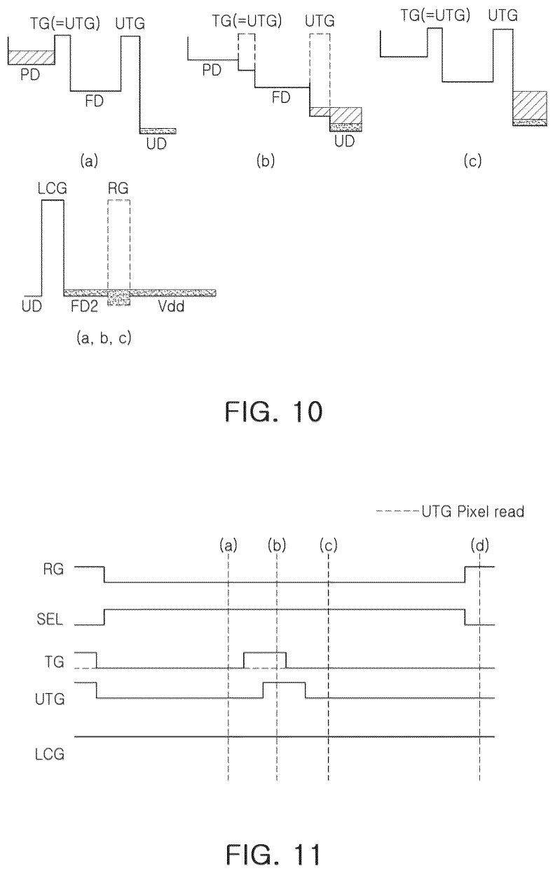

FIG. 9 is an operation timing diagram of a pixel processing circuit in a high conversion gain mode, and FIG. 10 is a potential diagram according to the operation timing steps in the high conversion gain mode.

Referring to FIGS. 9 and 10, only a first floating diffusion region UD may be used in the high conversion gain mode. To this end, a first transistor LCG may be turned off during an operational integration time (OIT), and a second floating diffusion region FD2 may not be connected to the first floating diffusion region UD. In addition, a reset transistor RG may be turned on to connect the second floating diffusion region FD2 to a pixel bias voltage (Vpix) node, thereby preventing the second floating diffusion region FD2 from floating. (See (a), (b) and (c) in FIG. 10).

Referring to FIG. 9, step (a) may be a photodiode (PD) charge accumulation step, in which negative charges are accumulated in an N-type region of the photodiode PD, while a transfer transistor TG is turned off. At this time, a transfer gate UTG may also remain turned off, thereby preventing the negative charges from moving to the first floating diffusion region UD and a floating diffusion region FD of an active region.

In step (b), the transfer transistor TG and the transfer transistor UTG may be turned on. First, when the transfer transistor TG is turned on, the negative charge accumulated in the photodiode PD may be moved to the floating diffusion region FD provided by the active region with a low potential. At the same time or subsequently, when the transfer gate UTG is turned on, since a potential of the first floating diffusion region UD is lower than a potential of the floating diffusion region FD included in the active region, the negative charges may be moved to the first floating diffusion region UD.

In step (c), the transfer gate UTG may be turned off after a predetermined time has elapsed, a source follower transistor SF may generate an electric signal in response to an amount of the charges stored in the first floating diffusion region UD, and then the electrical signal may be transmitted to an output line through a turned-on selection transistor SEL.

In step (d), after completing a reading of the pixel, the first transistor LCG may be turned on with the reset transistor RG turned on, and the transfer transistor TG and the transfer gate UTG may be turned on. By turning on all the transistors passing from the pixel bias voltage (Vpix) node to the photodiode PD, the negative charges may be removed from connection nodes including the photodiode PD and the first floating diffusion region UD.

In FIGS. 9 and 10, if the pixel to be read is a pixel to which the transfer gate UTG is connected in step (b), the transfer gate UTG may be turned on with the other transfer transistor TG turned off, as indicated by a dotted line.

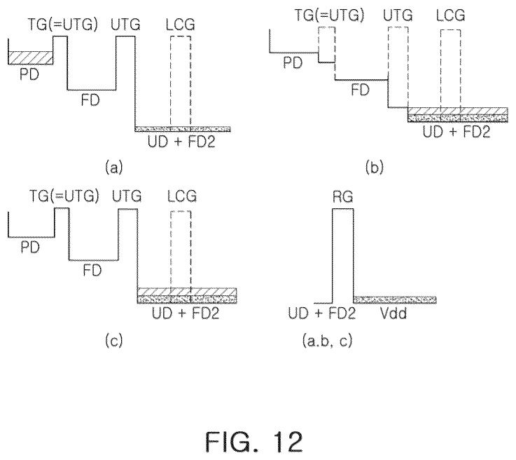

FIG. 11 is an operation timing diagram of a pixel processing circuit in a low conversion gain mode, and FIG. 12 is a potential diagram according to the operation timing steps in the low conversion gain mode.

Referring to FIGS. 11 and 12, both of a first floating diffusion region UD and a second floating diffusion region FD2 may be used in the low conversion gain mode. To this end, a first transistor LCG may be turned on during an operational integration time (OIT), and the second floating diffusion region FD2 may be connected to the first floating diffusion region UD (See (a), (b) and (c) in FIG. 12).

Referring to FIG. 11, step (a) may be a photodiode (PD) charge accumulation step, in which negative charges are accumulated in an N-type region of the photodiode PD, while a transfer transistor TG is turned off. At this time, a transfer gate UTG may be similarly turned off, thereby preventing the negative charges from moving to the first floating diffusion region UD and a floating diffusion region FD of an active region.

In step (b), the transfer transistor TG and the transfer transistor UTG may be turned on. First, when the transfer transistor TG is turned on, the negative charge accumulated in the photodiode PD may be moved to the floating diffusion region FD of the active region with a low potential. At the same time or subsequently, when the transfer gate UTG is turned on, since a potential of the first floating diffusion region UD is lower than a potential of the floating diffusion region FD included in the active region, the negative charges may be moved to the first floating diffusion region UD.

In step (c), the transfer gate UTG may be turned off after a predetermined time has elapsed, a source follower transistor SF may generate an electric signal in response to an amount of the charges stored in the first floating diffusion region UD and the second floating diffusion region FD2, and then the electrical signal may be transmitted to an output line through a turned-on selection transistor SEL.

In step (d), after completing a reading of the pixel, the reset transistor RG may be turned on with the first transistor LCG turned on, and the transfer transistor TG and transfer gate UTG may also be turned on. By turning on all the transistors passing from the pixel bias voltage (Vpix) node to the photodiode PD, the negative charges may be removed from connection nodes including the photodiode PD, the first floating diffusion region UD and the second floating diffusion region FD2.

In FIGS. 11 and 12, if the pixel to be read is a pixel on which the photodiode PD connected to the transfer gate UTG is disposed in step (b), the transfer gate UTG may be turned on with the other transfer transistor TG turned off, as indicated by a dotted line.

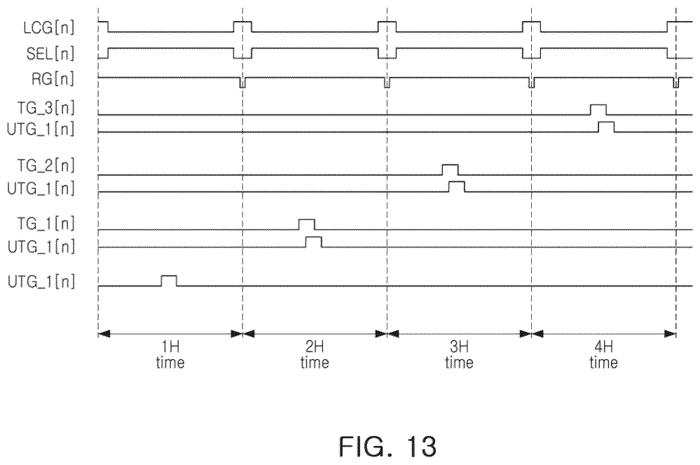

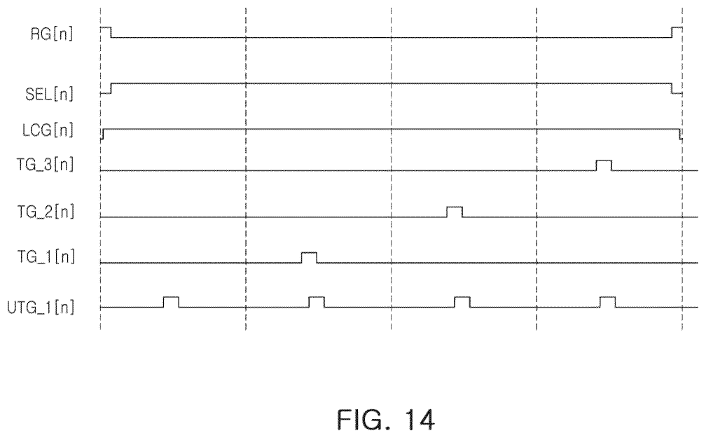

Next, FIGS. 13 and 14 relate to operating modes when a plurality of photodiodes are shared. FIG. 13 is an operation timing diagram in a four-sum operating mode according to an example embodiment of the disclosure.

Referring to FIG. 13, in an example embodiment of the disclosure, a high conversion gain mode with a small capacitance of a floating diffusion region may be set in order to operate in the four-some operating mode. To this end, a first transistor LCG may be turned off and only a first floating diffusion region UD may be used during an operation integration time. A reset transistor RG may be selectively turned on to prevent a voltage of a second floating diffusion region FD2 from floating.

During a first operating time (1H time), other transfer gates TG1 to TG3 may be turned-off and a transfer gate UTG1 may be turned on to read a pixel including a transfer gate UTG first. During the reading, a selection transistor SEL may be turned on to transmit an electrical signal to an output line.

Next, during a second operating time (2H time), the first transfer gate TG1 may be turned on, and the transfer gate UTGI may be turned on simultaneously or after a predetermined time. When the first transfer gate TG1 is turned on, negative charges collected in a photodiode disposed in the same pixel region as the first transfer gate TG1 may be transferred to a floating diffusion region included in an active region, and sequentially, may be transferred to the first floating diffusion region UD via the turned-on transfer gate UTG1.

Subsequently, during a third operating time (3H time), the second transfer gate TG2 may be turned on, and the transfer gate UTG1 may be turned on simultaneously or after a predetermined time. During a fourth operating time (4H time), the third transfer gate TG3 may be turned on, and the transfer gate UTG1 may be turned on simultaneously or after a predetermined time. As such, the negative charges collected from the photodiodes of the four pixel regions may be transferred to the first floating diffusion region UD, and an electrical signal generated based on an amount of the transferred charges (Q-CV) may be transmitted to an output line by the selection transistor SEL.

In an example of this embodiment, in a reset mode, the first transistor LCG may be turned on to initialize the first floating diffusion region UD in a state in which the reset transistor RG and the selection transistor SEL are turned off. Optionally, the reset transistor RG may be turned off for a certain time period to reduce power consumption.

The N-sum mode (i.e., a mode that uses a plurality of N pixels provided by N pixel regions as one cluster pixel) presented herein may realize low noise and high conversion gain while increasing a signal size in low illumination imaging situations.

FIG. 14 is an operation timing diagram in an individual pixel operating mode according to an example embodiment of the disclosure.

Referring to FIG. 14, in an example embodiment of the disclosure, a low conversion gain mode with a relatively large capacitance of a floating diffusion region may be set in order to operate in the individual pixel operating mode. To this end, a first transistor LCG may be turned on during an operation integration time, and a first floating diffusion region UD and a second floating diffusion region FD2 may be connected and used together.

During a first operating time (1H time), other transfer gates TG1 to TG3 may be turned-off and a transfer gate UTGI may be turned on to read a pixel including the transfer gate UTG first. During the reading, a selection transistor SEL may be turned on to transmit an electrical signal to an output line.

Next, during a second operating time (2H time), the first transfer gate TG1 may be turned on, and the transfer gate UTGI may be turned on simultaneously or after a predetermined time. When the first transfer gate TG1 is turned on, negative charges collected in a photodiode disposed in the same pixel region as the first transfer gate TG1 may be transferred to the floating diffusion region included in an active region, and sequentially, may be transferred to the first floating diffusion region UD via the turned-on transfer gate UTG1.

Subsequently, during a third operating time (3H time), the second transfer gate TG2 may be turned on and the transfer gate UTG1 may be turned on simultaneously or after a predetermined time. During a fourth operating time (4H time), the third transfer gate TG3 may be turned on, and the transfer gate UTGI may be turned on simultaneously or after a predetermined time. As such, the negative charges collected from the photodiodes of the respective pixel regions may be transferred to the first floating diffusion region UD and the second floating diffusion region FD2, and an electrical signal generated based on an amount of the transferred charges (Q=CV) may be output to the output line by the selection transistor SEL.

In an example of this embodiment, in a reset mode, the reset first transistor RG may be turned on to initialize the first floating diffusion region UD and the second floating diffusion region FD2 in a state in which the selection transistor SEL is turned off and the first transistor LCG transistor is turned on.

The individual pixel operating mode presented herein may realize a high-resolution image by increasing the number of pixels in a high illumination imaging situation, and may realize an image sensing device with a wide dynamic range.

For the purpose of the disclosure, the operating times (1H to 4H times) and the total operating time of the individual pixel operating mode may be the same as or different from the operating times and the total operating time of the four-sum operating mode.

Next, a manufacturing process of a pixel and a pixel processing circuit according to an example embodiment of the disclosure will be described. The disclosure may relate to an image sensing device manufactured in a back side incidence (BSI) method in which a deep photodiode with an N-type region of the photodiode extending into a substrate is formed, a lower surface of the substrate is removed to a certain depth, and then a lens and a color filter are formed on the lower surface of the substrate.

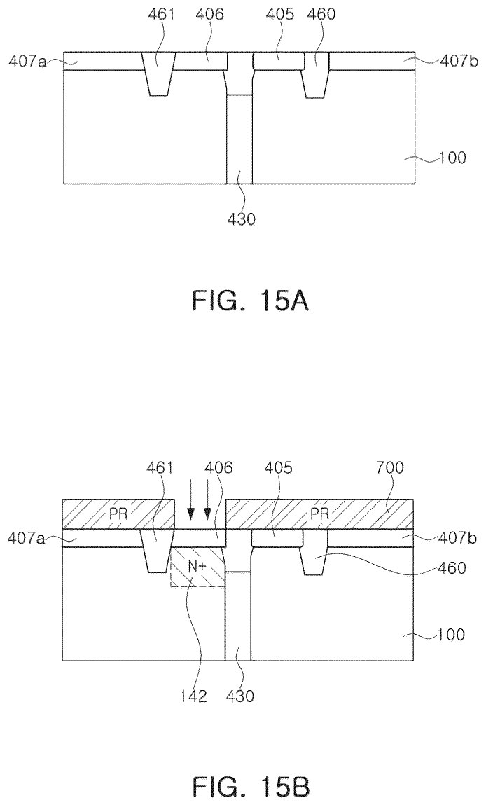

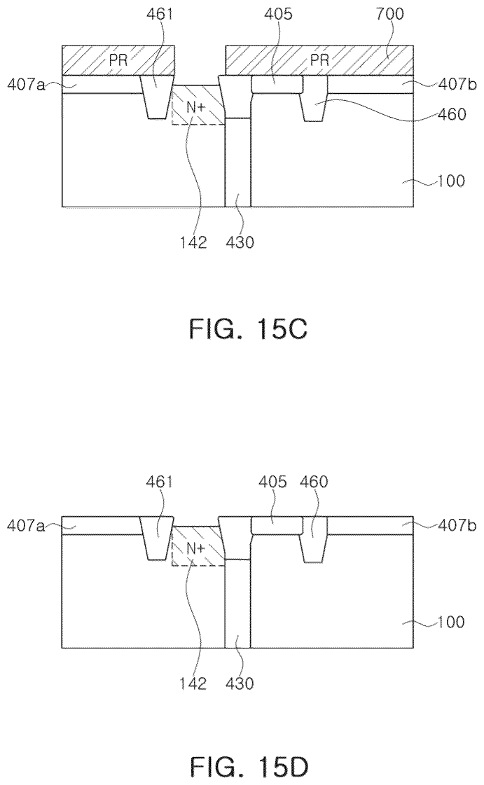

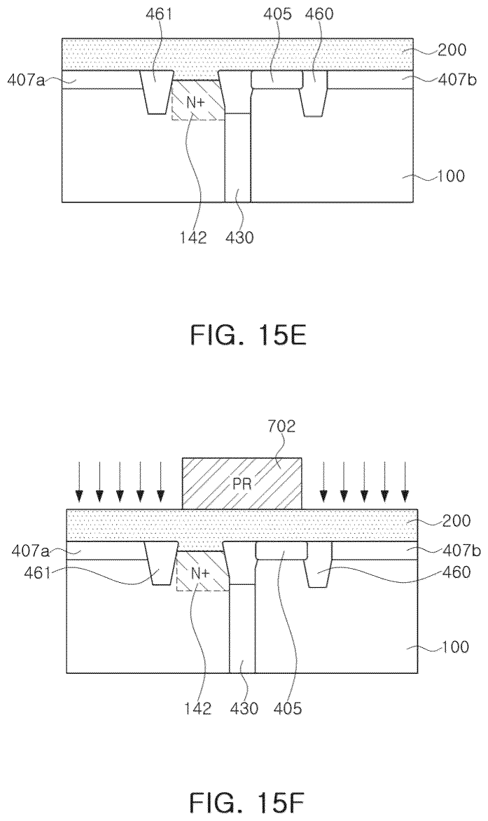

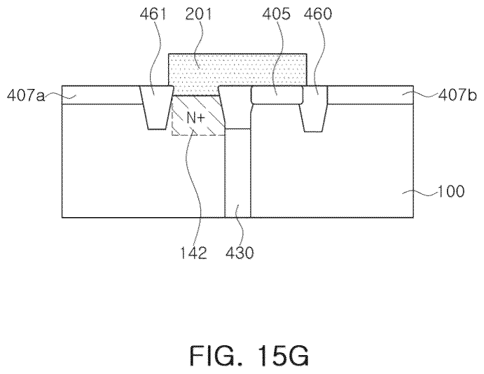

FIGS. 15A to 15G are manufacturing process diagrams of the source follower transistor and the first floating diffusion region according to an example embodiment of the disclosure.

Referring to FIG. 15A, STIs 460 and 461 and a DTI 430 may be formed as device isolation regions on an upper surface of a substrate 100. The substrate 100 has the upper surface and a lower surface, transistors including planar field effect transistors, FinFET transistors and the like may be formed on the upper surface, and various wirings may be formed in a post-process to connect the transistors to each other.

The substrate 100 may include a silicon substrate, a compound semiconductor (for example, indium phosphide (InP), gallium arsenide (GaAs), silicon germanium (SiGe), indium arsenide (InAs), silicon carbide (SiC) or other suitable compound semiconductor material) substrate. The silicon substrate may include a bulk silicon layer or a Silicon-On-Insulator (SOI) substrate layer.

The substrate 100 may be doped with one or more impurities, and an N-type substrate or a P-type substrate may be formed by the impurities. In an example embodiment, the substrate 100 may be a P-type substrate, and boron (B), aluminum (Al) and indium (In) dopants may be implanted into the substrate.

The device isolation regions may include the STIs 460 and 461, which are shallow trench isolation regions. The STIs 460 and 461 may be formed by forming an opening first by means of a photolithography technology, and then filling the opening with an insulating material such as SiO₂, SiₓN_{y} and a composite film.

Furthermore, the DTI 430 may be formed by forming a deep trench and filling it with an insulating material. In an example embodiment, the DTI 430 may be formed by drilling a deep trench directly on the upper surface of the substrate 100, and in another embodiment, the DTI 430 may be formed by forming a shallow trench, drilling a deep trench, and filing it with an insulating layer. The DTI 430 may separate pixel regions providing individual pixels included in the pixel array. In an example embodiment, a conductive material may be additionally formed inside the DTI 430 in order to apply a bias to the DTI 430. Polysilicon and tungsten may be used as the conductive material. An insulating layer may be applied on the substrate to insulate the conductive material.

Continuing to refer to FIG. 15A, an insulating film 405, 406, 407a and 407b may be applied to the upper surface of the substrate. The insulating film 405, 406, 407a and 407b may include a silicon oxide film, and may be further doped with nitrogen, carbon or other substances as long as the insulating properties are maintained. The insulating film may be formed using deposition and/or silicon oxidation methods. In an example embodiment, the insulating film 405 may be used as a gate oxide film of a source follower transistor SF.

Referring to FIG. 15B, a photoresist layer 700 may be applied and patterned on the upper surface of the substrate 100, and an ion implantation process may be performed with group 5 ions to form an ion doped region 142. Next, the exposed insulating film 406 may be removed as shown in FIG. 15C, and the photoresist layer 700 may be removed as shown in FIG. 15D.

Then, for example, a polysilicon film (polysilicon layer) 200 may be applied as a gate material as shown in FIG. 15E, and a photoresist may be applied and patterned to form a photoresist pattern 702, and the etching process may be performed, as shown in FIG. 15F. As a result, as shown in FIG. 15G, an gate extension 201e included in a gate of the source follower transistor SF 201 may substantially contact a first floating diffusion region UD 142 across the DTI 430.

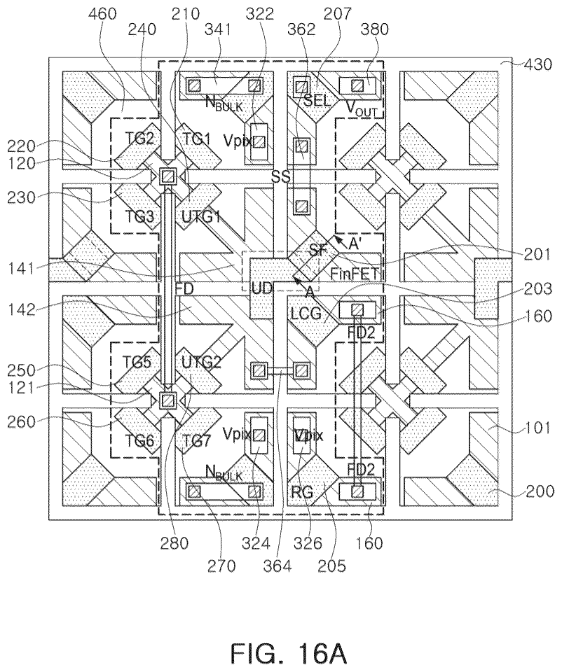

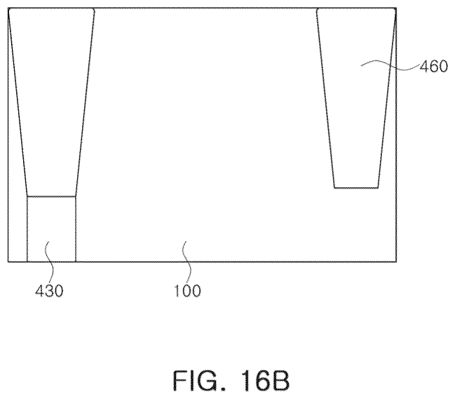

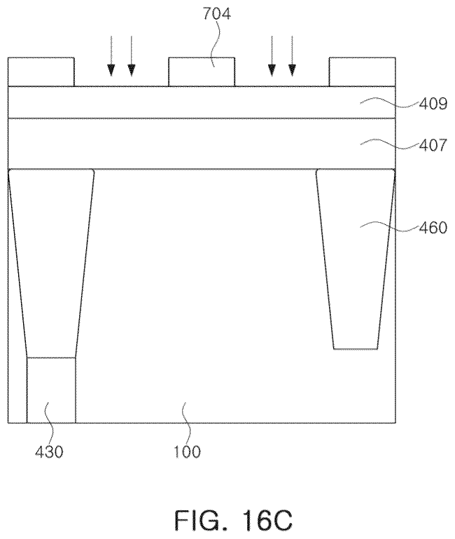

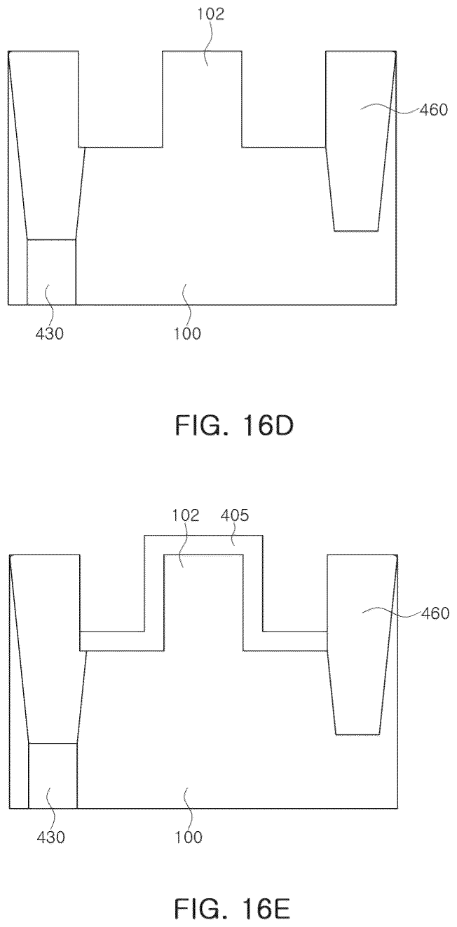

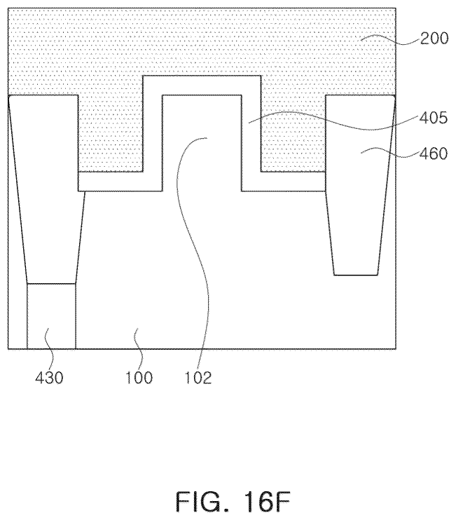

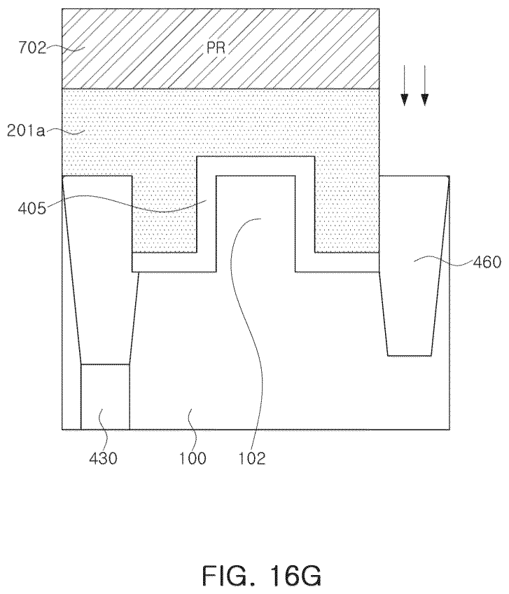

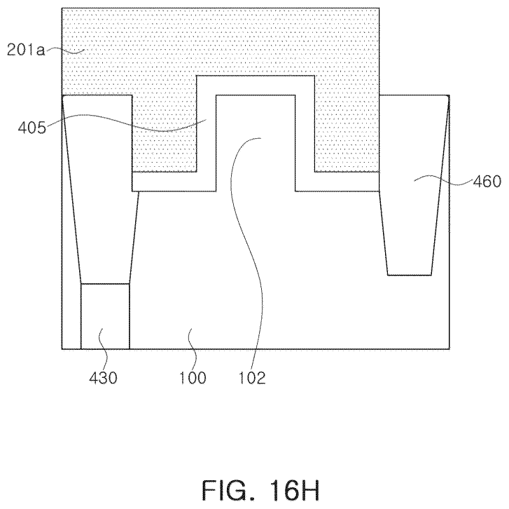

Next, a method of forming a FinFET type source follower transistor will be described. A DTI 430 cut in the A-A′ direction in FIG. 16A will also be described.

Referring to FIG. 16B, the DTI 430 and a STI 460 may be formed on an upper surface of a substrate 100 to define an active region of a source follower transistor.

Next, referring to FIG. 16C, a hard mask film 407 and an anti-reflection film 409 may be sequentially applied to the upper surface of the substrate, a photoresist layer 704 may be applied thereon to create a pattern, and then a region exposed in a direction of the upper surface may be etched, thereby forming a protrusion 102 on the upper surface of the substrate as shown in FIG. 16D. It is well known to those skilled in the art that a dry etching and/or a wet etching may be additionally performed to make a curved surface smooth.

Next, as shown in FIG. 16E, a gate oxide film 405 may be formed on the exposed upper surface, a polysilicon layer 200 may be applied as shown in FIG. 16F, and the polysilicon layer 200 may be patterned as shown in FIG. 16G. Next, referring to FIG. 16H, the photoresist pattern 702 may be removed to form a gate layer 201a. As shown in FIG. 16H, the gate 201a of the source follower transistor SF 201 may cover three sides of the protrusion 102 that corresponds to a fin structure with a gate oxide film 405 interposed therebetween, and may extend across the adjacent DTI 430 to a first floating diffusion region UD 141, 142 on the other side.

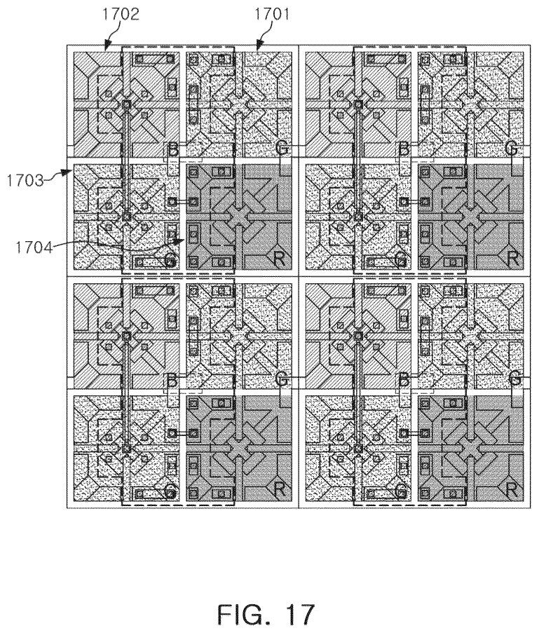

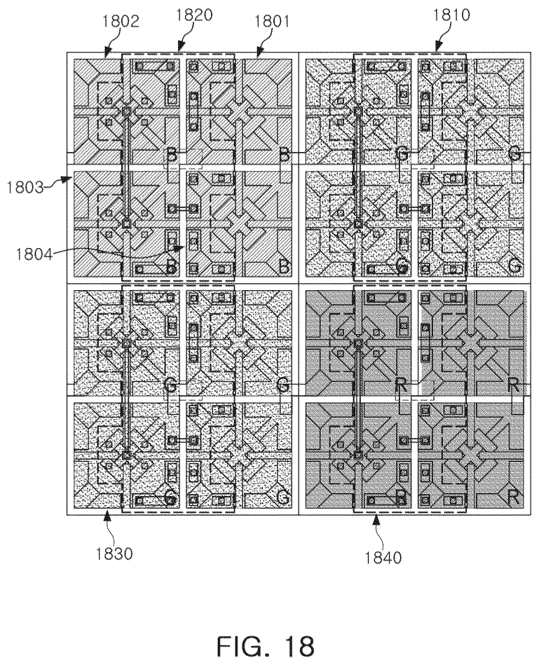

FIGS. 17 and 18 are diagrams exemplarily showing methods of forming a color filter and a lens on a lower surface of a substrate in an image sensing device of the disclosure.

FIG. 17 shows a pixel array in which four pixels are combined to form one color of a Bayer pattern according to an example embodiment of the disclosure. The pixel array may be arranged in a manner that creates a Bayer pattern, with four pixel regions in each quadrant sharing a color filter of the same color and possibly sharing one lens.

In an individual pixel operating mode, the respective pixels may operate as an individual pixel, such that all four pixels sharing a color filter of the same color can operate as an individual pixel.

In an N-sum operating mode (a mode that transmits an electrical signal to an output based on an amount of negative charges collected from N pixels), four pixels sharing a color filter of the same color may operate as one giant pixel (cluster pixel).

If assuming a layout in which eight pixels share one pixel processing circuit as shown in FIG. 2, only four pixels that use a color filter of the same color may be shared and operate as one cluster pixel in a high conversion gain mode.

Referring to FIG. 17, in an example embodiment, four blue pixels 1702 located in the second quadrant may share a pixel processing circuit with four green pixels 1703 located in the third quadrant there below, while four green pixels 1701 located in the first quadrant may share a pixel processing circuit with four red pixels 1704 located in the fourth quadrant.

In the high conversion gain mode, the photodiodes included in the four green pixels 1703 may be disconnected from the pixel processing circuit, while the photodiodes included in the four blue pixels 1702 may be connected to the pixel processing circuit to output an electrical signal. In an example embodiment of the disclosure, since the electrical signals of the pixel array are read simultaneously in a horizontal direction for each bit line, it may be appropriate for the shared pixels to be shared in a vertical direction.

Next, FIG. 18 realize a pixel block in which sixteen pixels are combined to represent one color according to shows another embodiment of the disclosure. Referring to FIG. 18, a green block 1810 containing sixteen pixels in the first quadrant, a blue block 1820 containing sixteen pixels in the second quadrant, a green block 1830 containing sixteen pixels in the third quadrant and a red block 1840 containing sixteen patterns in the fourth quadrant may be disposed to configure a Bayer pattern. Among these, referring to the blue block 1820 as an example, four pixels 1801 disposed in the first quadrant in the blue block 1820 and sharing one active region, four pixels 1802 disposed in the second quadrant in the blue block 1820 and sharing one active region, four pixels 1803 disposed in the third quadrant in the blue block 1820 and sharing one active region, and four pixels 1804 disposed in the fourth quadrant in the blue block 1820 and sharing one active region may be included. In the embodiment of FIG. 18, two active regions of the four pixels 1802 and the four pixels 1803 arranged up and down may be connected to each other. In this way, in the disclosure, the color filters may be arranged in various patterns, as exemplarily shown in FIGS. 17 and 18.

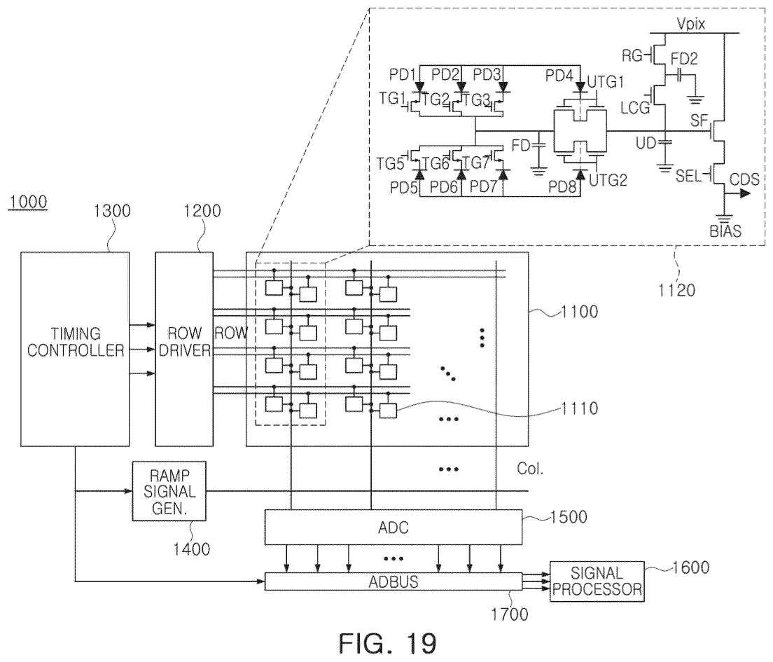

FIG. 19 is a block diagram of a CMOS image sensing device including a pixel and a pixel processing circuit according to an example embodiment of the disclosure.

Referring to FIG. 19, an image sensor 1000 of the disclosure may include a pixel array 1100, a row driver 1200, a timing controller 1300, a lamp signal generator 1400, an analog-digital converter (ADC) 1500, a signal processor 1600, and an ADBUS 1700.

The pixel array 1100 may include unit pixels 1110, and four shared photodiodes PD1 to PD4 and four shared photodiodes PD5 to PD8 may share one pixel processing circuit 1120. The four shared pixels may share one active region. Four pixels sharing an active region may share one output line with four other pixels sharing an active region in a row direction.

The timing controller 1300 may control an operation timing of the image sensor 1000. As an example, the timing controller 1300 may set a time taken to complete reading of output signals output from the shared pixels included in the pixel array 1100 depending on a low-resolution operating mode or a high-resolution operating mode, and may generate timing signals based on the set time. The timing controller 1300 may provide the timing signals to the row driver 1200, the ADC 1500, an output buffer, a column driver and the like. The timing controller 1300 may include or correspond to a microprocessor unit (MPU), an application processor (AP), a coprocessor (CP), a system-on-chip (SoC), or an integrated circuit (IC).

The row driver 1200 may generate signals to control the pixel array 1100. The row driver 1200 may provide a reset control signal, a transfer control signal and a selection signal to a plurality of pixels included in the pixel array 110 in response to the timing signals received from the timing controller 1300. The low driver 1200 may determine activation and deactivation timings of a plurality of reset control signals, a plurality of transfer control signal and a plurality of selection signals based on various operating modes (for example, a high conversion gain mode or a low conversion gain mode).

The ADC 1500 may convert an analog signal for each column output line into a digital signal. The ADC 1500 may include a plurality of comparators and a plurality of column counters. The ramp signal generator 1400 may generate a ramp signal that decreases or increases with a predetermined slope.

The address bus 1700 may be a path through which a pixel data signal is transmitted within the image sensor. The pixel signal converted into a digital signal in the ADC 150 may be transmitted to the signal processor 1600 via the address bus 1700.

The signal processor 1800 may perform various image processing, including improving an image quality of a signal generated from a pixel, for example, improving a signal-to-noise ratio and removing noise.

The signal processor 1800 may perform various image processing, including an offset compensation, an autofocus pixel designation and/or a bad pixel designation, a dark level compensation, and a digital gain compensation processing.

In an example embodiment of the disclosure, an image sensing device with high conversion gain may include a floating diffusion region with a less capacitance value.

In addition, an example embodiment of the disclosure may be directed to an image sensing device with low noise. According to an example embodiment of the disclosure, noise may be reduced by shortening the routing of a floating diffusion region and a source follower transistor. Alternatively, a signal-to-noise ratio (SNR) may be improved by implementing the gate of the source follower transistor as a FinFET type.

In additionally, an example embodiment of the disclosure may be directed to an image sensing device with a high dynamic range. In an example embodiment, a CMOS image sensing device capable of operating in multiple modes may be realized by operating in a high conversion gain mode in low illumination and operating in a low conversion gain mode in high illumination. In an example embodiment of the disclosure, an additional floating diffusion region may be connected to the source follower transistor and extend the floating diffusion region depending on the mode.

In an embodiment, an image sensing device may have a high dynamic range and/or low noise even in an architecture in which a plurality of pixels share a pixel processing circuit. Therefore, it may be possible to implement an image sensing device that satisfies the industry's demands for device integration and miniaturization.

Furthermore, while example embodiments have been shown and described above, it will be apparent to those skilled in the art that modifications and variations could be made without departing from the scope of the disclosure as defined by the appended claims.

The disclosure relates to a CMOS image sensing device, and operating and manufacturing methods of the same. The image sensing device described in various embodiments of the disclosure can operate in a high conversion gain mode and a low conversion gain mode, thereby providing a wide dynamic range. Embodiments embodied in accordance with the spirit of the disclosure and applied products of the disclosure can also be applicable to a mobile phone, an optical equipment, electronics, and security industries, and can be integrated with other industries.

1. A complementary metal-oxide-semiconductor (CMOS) image sensing device comprising:
a semiconductor substrate including a plurality of pixel regions;
an insulating film disposed within the semiconductor substrate and disposed between the plurality of pixel regions; and
a first active region disposed between the plurality of pixel regions,
wherein a photoelectronic conversion element and a transfer transistor are disposed in at least one of the plurality of pixel regions,
wherein the photoelectronic conversion element is connected to the first active region by the transfer transistor,
wherein the first active region and a first floating diffusion region are connected by at least one of the transfer transistors,
wherein the first floating diffusion region is connected to a gate of a source follower transistor, and the first floating diffusion region is connected to a second floating diffusion region through a first transistor, and
wherein the first transistor is turned off when an operating mode is a first mode, and the first transistor is turned on when the operating mode is a second mode different from the first mode.

2. The CMOS image sensing device of claim 1, wherein the second floating diffusion region is connected to a reset transistor, and
wherein the source follower transistor is connected to a selection transistor.

3. The CMOS image sensing device of claim 2, wherein a gate extension in the gate of the source follower transistor is connected to the first floating diffusion region across the insulating film.

4. The CMOS image sensing device of claim 1, wherein the insulating film is configured to penetrate a substrate or is a deep trench isolation (DTI).

5. The CMOS image sensing device of claim 1, wherein a conversion gain of at least one pixel provided by the plurality of pixel regions in the first mode is greater than a conversion gain of at least one pixel provided by the plurality of pixel regions in the second mode.

6. The CMOS image sensing device of claim 1, wherein the plurality of pixel regions are four pixel regions providing four pixels.

7. The CMOS image sensing device of claim 6, wherein the four pixels are configured to operate as a single pixel in the first mode.

8. The CMOS image sensing device of claim 6, wherein the four pixels are configured to operate as individual pixels in the second mode.

9. The CMOS image sensing device of claim 6, wherein the insulating film does not extend to a corner shared by the four pixel regions, and
wherein the first active region shared by the four pixel regions is located in the corner shared by the four pixel regions.

10. The CMOS image sensing device of claim 3, wherein the gate extension in the gate of the source follower transistor substantially contacts the first floating diffusion region, and
wherein a gate oxide film is between the semiconductor substrate and at least a portion of the gate of the source follower transistor, and
wherein at least the portion of the gate of the source follower transistor is different from the gate extension.

11. The CMOS image sensing device of claim 3, wherein the gate of the source follower transistor is connected to the first floating diffusion region by wirings.

12. The CMOS image sensing device of claim 1, wherein the gate of the transfer transistor is a dual vertical gate.

13. The CMOS image sensing device of claim 1, wherein the gate of the source follower transistor is a Fin Field-Effect Transistor (FinFET) type gate.

14. The CMOS image sensing device of claim 1, wherein at least one of the plurality of pixel regions comprises a node for applying a predetermined bias voltage to the semiconductor substrate, and
wherein the node is connected to an adjacent gate.

15. The CMOS image sensing device of claim 1, wherein the first active region comprises a floating diffusion region.

16. The CMOS image sensing device of claim 15, wherein a doping concentration of N-type impurities of the first floating diffusion region is greater than a doping concentration of N-type impurities of the floating diffusion region in the first active region.

17. The CMOS image sensing device of claim 15, wherein a potential of the first floating diffusion region is lower than a potential of the floating diffusion region in the first active region.

18. The CMOS image sensing device of claim 15, wherein an area of the floating diffusion region in the first active region is greater than an area of the first floating diffusion region.

19. (canceled)

20. The CMOS image sensing device of claim 1, wherein the plurality of pixel regions provide one cluster pixel, and other plurality of pixel regions adjacent to the plurality of pixels provide the other cluster pixel,
wherein a number of the plurality of pixel regions is equal to a number of the other plurality of pixel regions,
wherein a second active region is disposed between the other plurality of pixel regions, and
wherein the first active region and the second active region are connected by wirings.

21. An image sensor comprising:
a reset transistor connected to a pixel bias voltage node configured to supply a pixel bias voltage;
first to fourth transfer transistors connected between first to fourth photodiodes and a floating diffusion region, respectively;
a first transistor connected between the floating diffusion region and the reset transistor;
a source follower transistor connected to the floating diffusion region; and
a selection transistor connected between the source follower transistor and a column line,
wherein the reset transistor is turned on and the first transistor is turned off during a turn-on time of the selection transistor in a first mode, and the reset transistor is turned off and the first transistor is turned on during a turn-on time of the selection transistor in a second mode, and
wherein a conversion gain in the second mode is less than a conversion gain in the first mode.

22. (canceled)

23. (canceled)
